(19) United States
(12) Patent Application Publication
(10) Pub. No.: US 2026/0213520 A1
(43) Pub. Date: Jul. 23, 2026

(54) INTEGRATED CIRCUIT HAVING EMBEDDED CIRCUIT BREAKER

(71) Applicant: Monolithic Power Systems, Inc., Kirkland, WA (US)

(72) Inventors: Jinghai ZHOU, Bellevue, WA (US); Chiahsin CHANG, Sammamish, WA (US)

(21) Appl. No.: 19/252,873

(22) Filed: Jun. 27, 2025

Related U.S. Application Data
(60) Provisional application No. 63/748,569, filed on Jan. 23, 2025.

(51) Int. Cl. H02H 3/08; H02H 1/00

(52) U.S. Cl. CPC H02H 3/08; H02H 1/0007

(57) ABSTRACT

An integrated circuit assembly includes a high-side switch serially coupled to a low-side switch, a breaker controller having a control circuit and a driver circuit, and a power stage controller. The breaker controller is coupled across an input and output of the circuit breaker. The high-side switch is further coupled to the output of the circuit breaker. An output of the low-side switch is coupled to a power ground. In operation, the control circuit measures the voltage drop or current across the external circuit breaker to determine if the power stage controller or high side switch has an over-current condition. If an over-current condition is detected, the driver circuit switches off the circuit breaker. This action isolates a failing integrated circuit assembly from a power supply system and limits the power loss to prevent severe damage.

This application claims the benefit of U.S. Provisional Patent Application No. 63/748,569, filed Jan. 23, 2025, under 35 U.S.C. § 119(e).

### FIELD OF THE INVENTION

The present invention generally relates to electrical components, and more particularly but not exclusively relates to integrated circuits.

### BACKGROUND OF THE INVENTION

With the increasing power consumption, a multiphase voltage regulator (VR) is required to supply higher power and better performance. In general, a power supply system uses Electronic-Fuse (EFuse) to limit the input supply power consumption in case of catastrophic device damage. However, when the EFuse is used for whole power supply system or for each rail only, its power limit is still too high for each phase circuit. When one phase circuit got damaged, the energy dumped to the failed device is too high causing the severe burnt and also burnt the PCB most of time.

### SUMMARY

An integrated circuit (IC) package having an embedded breaker controller that couples to a circuit breaker to isolate an integrated circuit having an over-current condition from a power supply system and limit the power loss to prevent severe damage is disclosed according to embodiments of the invention. The circuit breaker may be a fuse or a FET. Within the IC package, a power stage die includes a high-side switch, a low-side switch, a breaker controller, and a power stage controller. The breaker controller is coupled across a drain and a source of the external circuit breaker. The high-side switch is coupled between the source of the external circuit breaker and a drain of the low-side switch. A source of the low-side switch is coupled to a power ground (GND).

In operation, when a control circuit within the breaker controller determines the voltage drop across the circuit breaker and determines that the connected integrated circuit has an over-current condition, a driver circuit within the breaker controller circuit switches the circuit breaker off. This action isolates a failing integrated circuit to allow the remaining integrated circuits to keep the power supply system running.

### BRIEF DESCRIPTION OF DRAWINGS

The present invention can be further understood with reference to the following detailed description and the appended drawings, wherein like elements are provided with like reference numerals. These drawings are only for illustration purpose, thus may only show part of the devices and are not necessarily drawn to scale.

FIG. 1 shows a schematic diagram of an integrated circuit 100 in accordance with an embodiment of the present invention.

FIG. 2 shows a cross-sectional view of an integrated circuit 200 in accordance with an embodiment of the present invention.

FIG. 3 shows a top plan view of the integrated circuit 200 in accordance with an embodiment of the present invention.

FIG. 4 shows a cross-sectional view of an integrated circuit 300 in accordance with an embodiment of the present invention.

FIG. 5 shows a cross-sectional view of an integrated circuit 300A in accordance with an embodiment of the present invention.

FIG. 6 shows a top plan view of the integrated circuit 300A in accordance with an embodiment of the present invention.

FIG. 7 shows a schematic diagram of a power supply system 400 including a plurality of integrated circuits 100 of FIG. 1 in accordance with an embodiment of the present invention.

FIG. 8 shows a schematic diagram of an integrated circuit 500 in accordance with an embodiment of the present invention.

FIG. 9 shows a schematic diagram of a power supply system 600 in accordance with an embodiment of the present invention.

FIG. 10 shows a method 700 in accordance with the embodiment shown in FIG. 9.

### DETAILED DESCRIPTION OF THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

Embodiments of the present invention provide kinds of distributed circuit breaker embedded in each integrated circuit, to provide an isolation of an integrated circuit having an over-current condition from a power supply system and limit the power loss to prevent severe damage. The over-current condition indicates that the integrated circuit is failing or has failed. The circuit breaker may be a fuse or a FET. The power supply system including a plurality of paralleled integrated circuits is allowed to continue providing power to a load (e.g., CPU, GPU, etc.) even if one or more of the integrated circuits is failing or has failed, to prevent unexpected data loss. Further, while the disclosed embodiments describe using nFET technology, the concept can be extended to pFET technology.

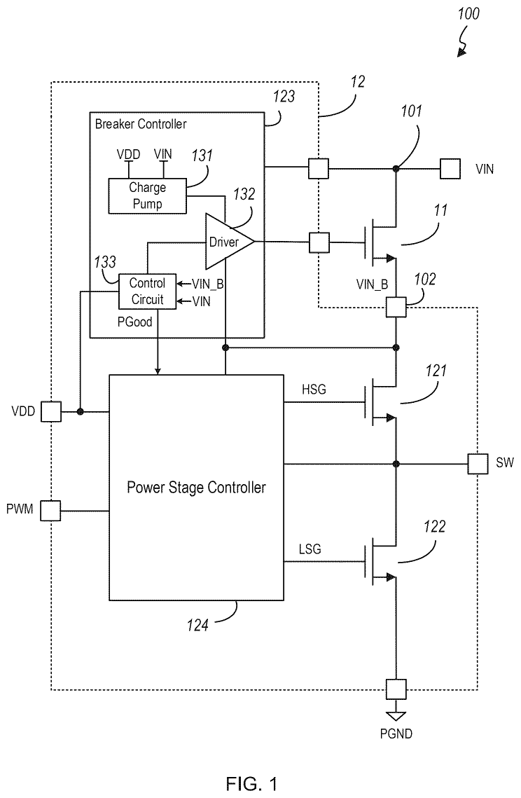

FIG. 1 shows a schematic diagram of an integrated circuit 100 in accordance with an embodiment of the present invention. The integrated circuit 100 is an implementation of a power stage which integrates a breaker circuit 11 and a power stage die 12 in a single package. In one embodiment, the power stage die 12 comprises a high-side switch 121, a low-side switch 122, a breaker controller 123, and a power stage controller 124. The high-side switch 121 and the low-side switch 122 form a switch node SW. In one embodiment, each of the high-side switch 121 and the low-side switch 122 comprises a MOSFET. A drain of the high-side switch 121 connects to the input node 101 through the circuit breaker 11, a source of the high-side switch 121 is coupled to a drain of the low-side switch 122 at the switch node SW, and a source of the low-side switch 122 is coupled to a power ground PGND. In the example of FIG. 1, the low-side switch 122 is integrated in the power stage die 12. In another example, the low-side switch 122 could also be placed outside of the power stage die 12.

The circuit breaker 11 is coupled in series with the high-side switch 121. In one embodiment, the circuit breaker 11 comprise a MOSFET. In operation, the circuit breaker 11 isolates the failing integrated circuit 100 during operation to allow other good integrated circuits (not shown in FIG. 1) to keep the power supply system running. In one embodiment, the circuit breaker 11 has a first node (e.g., a drain) coupled to an input node 101 to receive an input voltage VIN, a second node (e.g., a source) coupled to the drain of the high-side switch 121 to form a node 102, and a third node (e.g., a gate) coupled to the breaker controller 123. When the circuit breaker 11 is turned on, the circuit breaker 11 electrically connects the node 102 to the input node 101, such that a voltage VIN_B is supplied to the drain of the high-side switch 121. When the circuit breaker 11 is turned off, the circuit breaker 11 disconnects the node 102 from the input node 101, such that the high-side switch 121 is isolated from the input voltage VIN.

In one embodiment, the breaker controller 123 turns on and turns off the circuit breaker 11 based on a difference between the input voltage VIN and the voltage VIN_B (i.e. VIN-VIN_B, the voltage drop across the circuit breaker 11). When the breaker controller 123 judges that the integrated circuit 100 is damaged or the high-side switch 121 is failing, the circuit breaker 11 is switched off.

As shown in FIG. 1, the breaker controller 123 comprises a driver 132, a power supply circuit 131 (e.g., a charge pump) to power the driver 132, and a control circuit 133. The control circuit 133 is coupled to the driver 132 to turn on and turn off the circuit breaker 11 based on the input voltage VIN and the voltage VIN_B. In one embodiment, when the voltage drop across the circuit breaker 11 is higher than an over-current condition threshold voltage (e.g., 1V), the breaker controller 123 determines that the integrated circuit 100 is failing, the driver 132 switches the circuit breaker 11 off. The over-current condition threshold may be selected to identify a failed condition or a potential failure condition. The control circuit 133 further provides an indication signal PGood to a power stage controller 124. The power stage controller 124 receives a switching control signal PWM and the indication signal PGood, provides a drive signal HSG to drive the high-side switch 121 and a drive signal LSG to drive the low-side switch 122 based on the switching control signal PWM and the indication signal PGood. When the indication signal PGood indicates that there is no over-current condition is found by the breaker controller 133, the power stage controller 124 is active to the drive signals HSG and LSG based on the switching control signal PWM. As shown in FIG. 1, the power stage controller 124 further receives a voltage VDD.

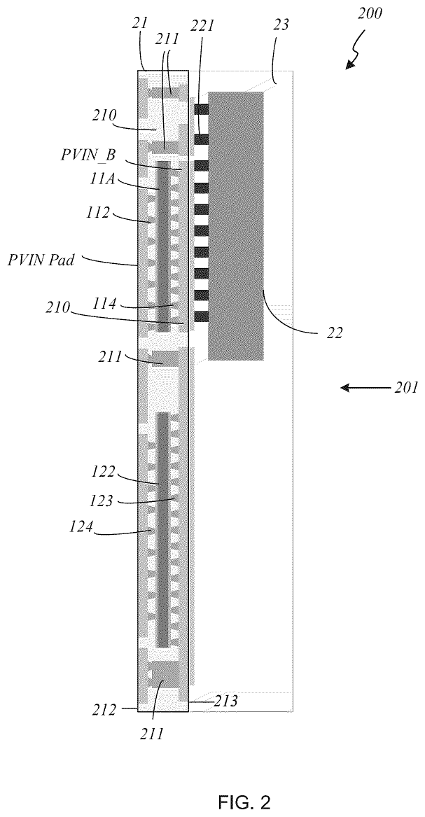

FIG. 2 shows a cross-sectional view of an integrated circuit 200 in accordance with an embodiment of the present invention. The integrated circuit 200 is a particular implementation of the integrated circuit 100 shown in FIG. 1, that the breaker controller 123, the high-side switch 121 and the power stage controller 124 (referring FIG. 1) are integrated into a power stage die 22, a breaker MOSFET 11A as an implementation of the circuit breaker 11 and a low-side switch 122 are embedded in a bottom substrate 21. The bottom substrate 21 has a top surface 213 and a bottom surface 212. A bottom surface of the power stage die 22 has a plurality of contact 221 attached to the top surface 213 of the bottom substrate 21, to electrically connect nodes of the power stage die 22 to pads on the top surface 213 of the bottom substrate 21. FIG. 2 also shows a reference arrow 201 that points towards the bottom substrate 21.

In one embodiment, the breaker MOSFET 11A is placed below the power stage die 22, and a projection of the power stage die 22 covers at least part of the breaker MOSFET 11A to minimize a parasitic inductance between the breaker MOSFET 11A and the high-side switch 121.

As shown in FIG. 2, the bottom substrate 21 further includes a plurality of conductive paths 211 (e.g., copper pillars) embedded in. Other empty regions of the bottom substrate 21 are filled with dielectric materials 210. The plurality of conductive paths 211 are electrically connected pads on the top surface 213 of the bottom substrate 21 to pads on the bottom surface 212 of the bottom substrate 21. The MOSFET 11A is electrically connected to the power stage die 22, e.g., through a plurality of vias 114 and pads on the top surface 213. The MOSFET 11A is further electrically connected to a pad PVIN1 (referring the node 101 used to receive the input voltage VIN) on the bottom surface 212 through a plurality of vias 112. More specifically, the MOSFET 11A has a plurality of source contact pads on a top surface of the MOSFET 11A and a plurality of drain contact pads on a bottom surface of the MOSFET 11A. The plurality of source contact pads are electrically connected to the power stage die 22, and the plurality of drain contact pads are electrically connected to the pad PVIN to receive the input voltage VIN.

As shown in FIG. 2, the low-side switch 122 has a plurality of contact pads on a top surface of the low-side switch 122 and a plurality of contact pads on a bottom surface of the low-side switch 122. The plurality of contact pads on the top surface of the low-side switch 122 are electrically connected to pads on the top surface 213 of the bottom substrate 21 through a plurality of vias 123, and the plurality of contact pads on the bottom surface of the low-side switch 122 are electrically connected to pads on the bottom surface 212 of the bottom substrate 21. The low-side switch 122 is electrically connected to the power stage die 22 to form the switch node SW (referring FIG. 1), and electrically connected to the power ground PGND. Other empty regions of the integrated circuit 200 are filled with a molding compound 23.

The breaker MOSFET 11A is coupled in series with the power stage die 22 to block the input voltage VIN in case of the integrated circuit 200 failing (e.g., the power stage die 22 is failing). The breaker MOSFET 11A could isolate the failing integrated circuit 200 during operation to limit the power consumption directly from the input voltage VIN to minimize the damage and prevent further damage during power recycling of the power supply system. The failing condition is reported back to the power supply system and the remaining integrated circuits of the power supply system could keep normally working unaffected by the failing integrated circuit 200.

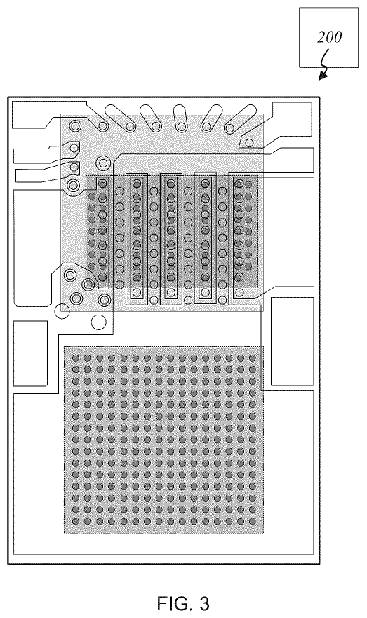

FIG. 3 shows a top plan view of the integrated circuit 200 in accordance with an embodiment of the present invention. FIG. 3 represents a view in the direction of the arrow 201 shown in FIG. 2. Some of the components (e.g., the power stage die 22, the breaker MOSFET 11A, and the low-side switch 122) are transparent for illustration.

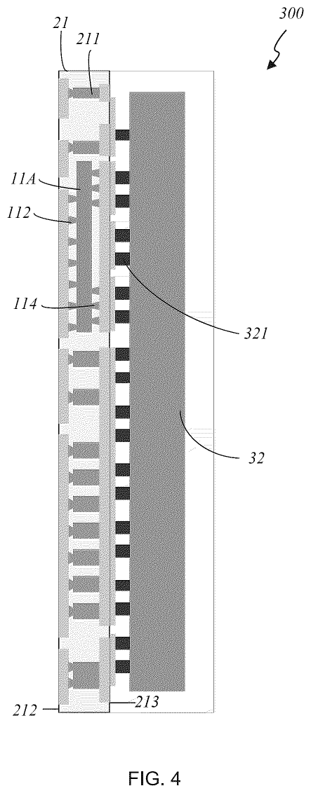

FIG. 4 shows a cross-sectional view of an integrated circuit 300 in accordance with an embodiment of the present invention. The integrated circuit 300 is a particular implementation of the integrated circuit 100 shown in FIG. 1, that the breaker controller 123, the high-side switch 121 and the low-side switch 122, and the power stage controller 124 (referring FIG. 1) are integrated into a power stage die 32, the breaker MOSFET 11A is embedded in the bottom substrate 21. A bottom surface of the power stage die 32 has a plurality of contact pads 321 attached to the top surface 213 of the bottom substrate 21, to electrically connect nodes of the power stage die 32 to pads on the top surface 213 of the bottom substrate 21.

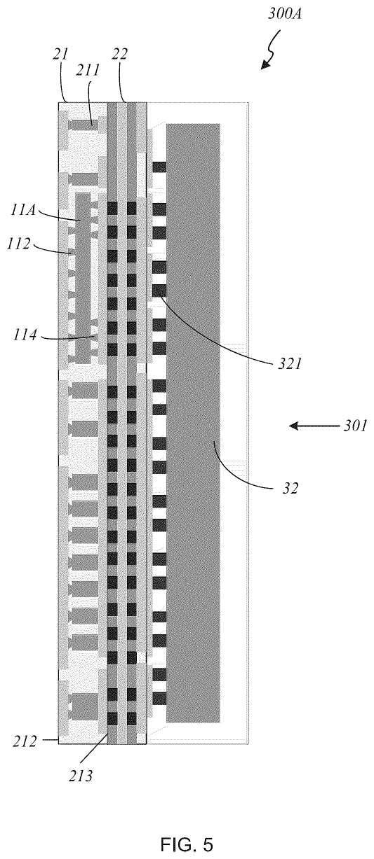

FIG. 5 shows a cross-sectional view of an integrated circuit 300A in accordance with an embodiment of the present invention. The integrated circuit 300A is a particular implementation of the integrated circuit 100 shown in FIG. 1, that the breaker controller 123, the high-side switch 121 and the low-side switch 122, and the power stage controller 124 (referring FIG. 1) are integrated into the power stage die 32, the breaker MOSFET 11A is embedded in the bottom substrate 21. Compared with the integrated circuit 300 shown in FIG. 4, the integrated circuit 300A further has a layer 22 which includes a plurality of conductive paths electrically connected the plurality of contact pads 321 of the power stage die 32 to pads on the top surface 213 of the bottom substrate 21. In one embodiment, the layer 22 is integrated into the bottom substrate 21 and is placed on a top end of the bottom substrate 21. In another embodiment, the layer 22 is a single layer independent of the bottom substrate 21.

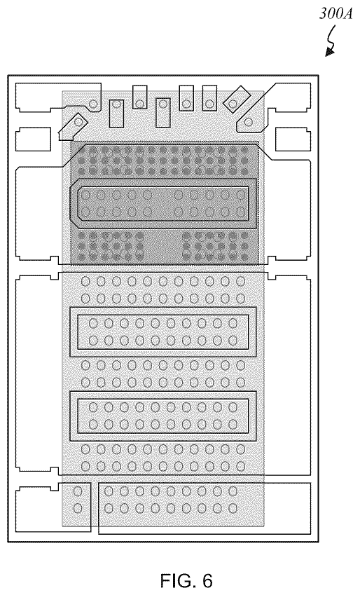

FIG. 6 shows a top plan view of the integrated circuit 300A in accordance with an embodiment of the present invention. FIG. 6 represents a view in the direction of the arrow 301 shown in FIG. 5. Some of the components (e.g., the power stage die 32 and the breaker FET 11A) are transparent for illustration.

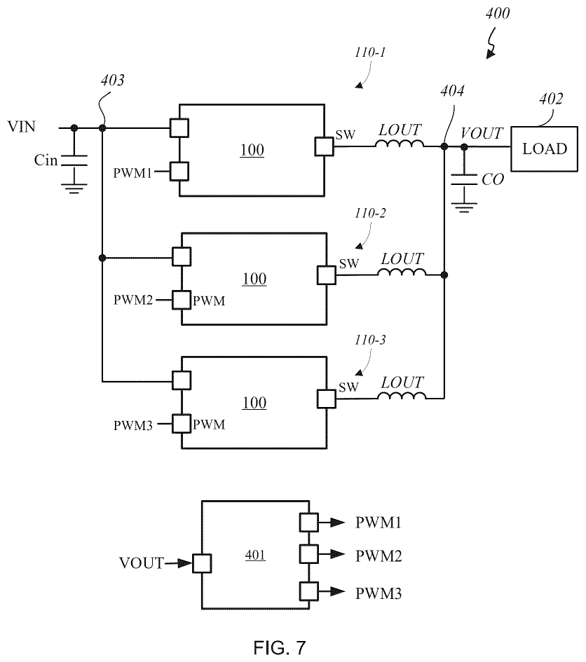

FIG. 7 shows a schematic diagram of a power supply system 400 including a plurality of integrated circuits 100 of FIG. 1 in accordance with an embodiment of the present invention. As shown in FIG. 7, the power supply system 400 has a plurality of phase circuit 110 (i.e., 110-1, 110-2, 110-3) coupled in parallel to receive the input voltage VIN and supply an output voltage VOUT to a load 402. Each phase circuit 110 includes one integrated circuit 100 and an output inductor LOUT, the output inductor LOUT in each phase circuit 110 is coupled between the switch node SW and an output node 404. In the example of FIG. 7, the power supply system 400 has three phase circuits as one example. More or less phase circuits 110 could be included for different applications. In other examples, the phase circuits 110 may provide a plurality of output voltages. A controller 401 is employed to provide the switching control signal PWM1-PWM3 based on the output voltage VOUT, to control the integrated circuit 100 in each phase circuit 110 respectively.

As described above, since each integrated circuit 100 has the circuit breaker 11 (referring FIG. 1) embedded in, a failing phase circuit could be disconnected from the input voltage VIN. For embodiments of the present invention, the embedded circuit breaker 11 will isolate the failing device while allowing the remaining good devices to continue to regulate the output voltage to keep system running and minimize the chance of data loss.

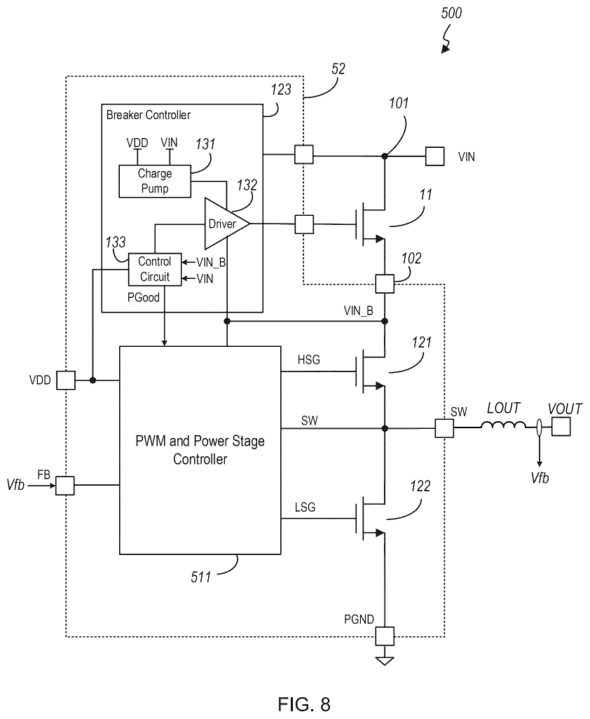

FIG. 8 shows a schematic diagram of an integrated circuit 500 in accordance with an embodiment of the present invention. The integrated circuit 500 is an implementation of a regulator (e.g., point of load regulator) including a breaker circuit 11 and a power stage die 52 integrated in one package. The switch node SW is coupled to the output inductor LOUT to provide the output voltage VOUT. The power stage die 52 comprises the high-side switch 121, the low-side switch 122, the breaker controller 123, and a power stage controller 511. The power stage controller 511 is configured to receive a feedback signal Vfb representative of the output voltage VOUT, and provide the drive signal HSG and the drive signal LSG based on the feedback signal Vfb. In the example of FIG. 8, the low-side switch 122 is integrated in the power stage die 52. In another example, the low-side switch 122 could also be placed outside of the power stage die 52.

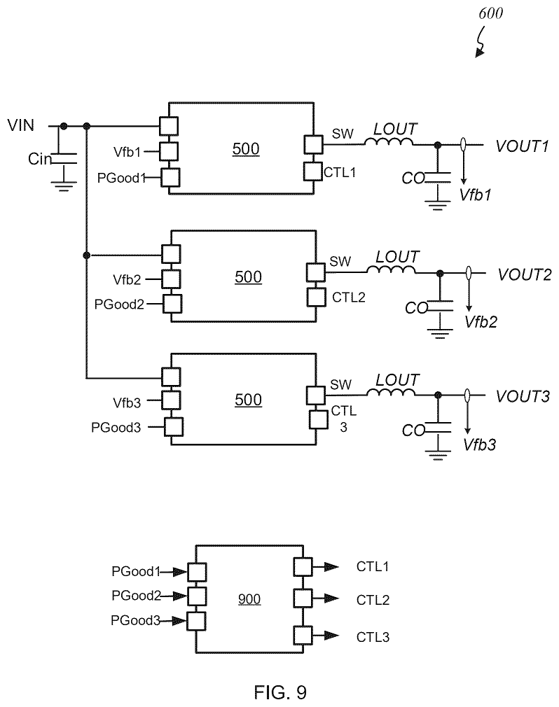

FIG. 9 shows a schematic diagram of a power supply system 600 including a plurality of integrated circuits 500 of FIG. 8 in accordance with an embodiment of the present invention. Each of the integrated circuits 500 is coupled to a system controller 900 and provides a corresponding indication signal PGood. The system controller 900 in response to receiving the indication signal PGood sends a corresponding control signal to at least one of the plurality of circuits 500. The control signal indicates an operational function. These operational functions include shutting down the whole power supply system, resetting the individual integrated circuit, requesting diagnostics from the integrated circuit, and an user alert.

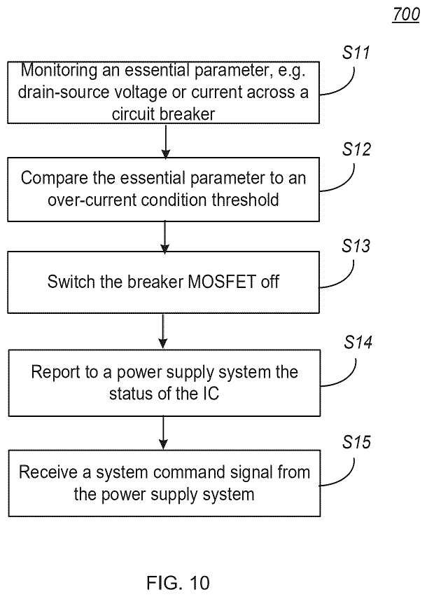

FIG. 10 shows a method 700 in accordance with an embodiment of the present invention. The method 700 comprises steps S11-S15. While the disclosed embodiments disclose monitoring the parameter of drain-source voltage for the circuit breaker MOSFET. The inventive concept is easily extended to monitor the parameter of current through the circuit breaker MOSFET when the circuit breaker is a built-in current sensing FET.

At step S11, monitoring an essential parameter, e.g. drain-source voltage or current, across a circuit breaker MOSFET.

At step S12, comparing the essential parameter to an over-current condition threshold. When the essential parameter is in excess of the over-current threshold, the integrated circuit is failing. The over-current condition threshold may be set to indicate failure or potential failure.

At step S13, switching the circuit breaker MOSFET off.

At step S14, reporting the over-current condition back to a power supply system in response to the integrated circuit is failing.

At step S15, receiving a system control signal from the power supply system. The system control signal indicates an operational function. These operational functions include resetting the individual integrated circuit after a predetermined time and requesting diagnostics from the integrated circuit.

While specific embodiments of the present invention have been provided, it is to be understood that these embodiments are for illustration purposes and not limiting. Many additional embodiments will be apparent to persons of ordinary skill in the art reading this disclosure.

We claim:

1. An integrated circuit assembly comprising:
a high-side field-effect transistor (FET) having an input configured to be coupled to an output of a circuit breaker and an output configured to provide an output signal;
a low-side FET having an input coupled to the output of the high-side FET and an output coupled to ground;
a breaker controller including,
a control circuit, configured to be coupled to an input and the output of the circuit breaker, operative to produce an indication signal in response to comparing a parameter across the circuit breaker to an over-current condition threshold, and
a breaker drive circuit, configured to be coupled to the control circuit and the circuit breaker, in response to the indication signal indicating an over-current condition producing a drive signal operative to turn off the circuit breaker; and
a switching drive circuit coupled to the control circuit and a gate of the high-side FET, the switching drive circuit operative to produce a high-side drive signal to turn off the high-side FET when the indication signal indicates an over-current condition.

2. The integrated circuit assembly of claim 1, wherein the circuit breaker is a fuse.

3. The integrated circuit assembly of claim 1, wherein:
the circuit breaker is a FET, and the breaker drive circuit is configured to be coupled to a gate of the FET.

4. The integrated circuit assembly of claim 3, further comprising the circuit breaker.

5. The integrated circuit assembly of claim 3, wherein the switching drive circuit is further coupled to the gate of the low-side FET, the switching drive circuit operative to produce a low-side drive signal in response to the indication signal, when the indication signal indicates an over-current condition the low-side drive signal turns off the low-side FET.

6. The integrated circuit assembly of claim 3, wherein the switching drive circuit is a power stage controller coupled to the control circuit to receive the indication signal, wherein the power stage controller is configured to receive a switching control signal from a controller, and further configured to control the high-side FET and low-side FET based on the switching control signal and indication signal.

7. The integrated circuit assembly of claim 3, wherein the over-current condition threshold indicates a failed integrated circuit assembly.

8. The integrated circuit assembly of claim 3, wherein the over-current condition threshold indicates a failing integrated circuit assembly.

9. The integrated circuit assembly of claim 1, wherein the parameter across the circuit breaker is selected from a group consisting of voltage and current.

10. A power supply system comprising:
an array of power controller assemblies, each power controller assembly including,
a circuit breaker,
a high-side field-effect transistor (FET) having an input coupled to an output of the circuit breaker,
a low-side FET having an input coupled to an output of the high-side FET and an output coupled to ground,
a breaker controller including,
a control circuit, coupled to an input and the output of the circuit breaker, operative to produce an indication signal in response to comparing a voltage drop across the circuit breaker to an over-current condition threshold, and
a breaker drive circuit, coupled to the control circuit and the circuit breaker, in response to the indication signal indicating an over-current condition producing a drive signal operative to turn off the circuit breaker, and
a power stage controller coupled to the control circuit and the gate of the high-side FET, the power stage controller operative to produce a high-side drive signal to turn off the high-side FET when the indication signal indicates an over-current condition; and
a system controller, coupled to the array of power controller assemblies, in response to receiving an indication signal from one of the array of power controller assemblies producing a system command signal.

11. The power supply system of claim 10, wherein the system command signal is selected from a group of operational parameters consisting of individual controller diagnostics, individual controller reset, and user alerts.

12. The power supply system of claim 10, wherein at least one of the array of power controller assemblies further comprising:
the power stage controller further coupled to the gate of the low-side FET, the power stage controller operative to produce a low-side drive signal in response to the indication signal, when the indication signal indicates an over-current condition the low-side drive signal turns off the low-side FET.

13. A method for detecting an over-current condition comprising:
monitoring a parameter of a circuit breaker;
comparing the parameter to an over-current condition threshold;
turning off the circuit breaker when the parameter is greater than the over-current condition threshold;
reporting the over-current condition to a system controller of a power supply system.

14. The method for detecting an over-current condition of claim 13, further comprising receiving a command from the system controller indicating an operational function.

15. The method for detecting an over-current condition of claim 14, wherein the operational function is selected from a group consisting of resetting an individual integrated circuit after a predetermined time and requesting diagnostics from the individual integrated circuit.

16. The method for detecting an over-current condition of claim 13, wherein the parameter is a voltage drop across the circuit breaker.

17. The method for detecting an over-current condition of claim 13, wherein when the circuit breaker is a built-in FET, the parameter is the current of the FET.
